(19) United States
(12) Patent Application Publication
(10) Pub. No.: US 2003/0011018 A1
(43) Pub. Date: Jan. 16, 2003

(54) Flash floating gate using epitaxial overgrowth

(76) Inventor: Kelly T. Hurley, Boise, ID (US)

Correspondence Address: David J. Paul, Agent for Applicant, Micron Technology, Inc., 8000 S. Federal Way, MS 525, Boise, ID, 83716, US

(21) Appl. No.: 09/905,584

(22) Filed: Jul. 13, 2001

(51) Int. Cl. H01L 29/76; H01L 31/062; H01L 21/336; H01L 29/788; H01L 29/94; H01L 31/113; H01L 31/119

(52) U.S. Cl. 257/314; 257/321; 257/377; 257/382; 438/257; 438/264

(57) ABSTRACT

A flash memory device comprising an epitaxial silicon floating gate containing conductive ions and overlying a tunnel oxide material; an inner-dielectric material overlying the epitaxial silicon floating gate, a polycide material overlying the inner-dielectric material, the tunnel oxide material, the epitaxial silicon floating gate, the inner-dielectric material and the polycide material forming a transistor gate, and source and drain electrodes on opposing sides of the transistor gate. A method for forming a flash memory device comprises forming a tunnel oxide with openings therein to expose underlying silicon forming a conductively doped epitaxial silicon layer over the tunnel oxide, forming an inner-dielectric layer over the epitaxial silicon layer, forming a polycide layer over the inner-dielectric layer; forming transistor gates from the polycide layer, the inner-dielectric layer, the epitaxial silicon layer and the tunnel oxide, and forming source and drain electrodes on opposing sides of the transistor gates.

### FIELD OF THE INVENTION

This invention relates to semiconductor fabrication processing and, more particularly, to a fabrication method for forming storage cells in semiconductor devices, such as non-volatile flash memory devices.

### BACKGROUND OF THE INVENTION

Non-volatile semiconductor memory devices are currently used extensively through the electronics industry. One type of non-volatile semiconductor memory devices employs the use of floating gate memory cells that are able to retain and transfer charge through a variety of mechanisms which include avalanche injection, channel injection, tunneling, etc. A flash memory device is such a semiconductor device that utilizes a floating gate memory cell. As is the case with most semiconductors being fabricated, the industry continues to push for smaller devices that contain a larger number of memory cells than each previous generation. This is also the case for the flash memory device.

In a flash memory device, fabrication of the components that make up the floating gate transistor determines the ability of the device to be programmed and retain an electrical charge as well as the ability of the device to be reprogrammed by being erased (or the removal of the electrical charge). Flash memory cells comprising floating gate transistors are laid out in such a manner that a plurality of cells forms a memory array.

A device in the programmed state, i.e., charge stored on the floating gate, represents a stored “0” and a device in the non-programmed state, i.e., no charge stored on the floating gate, represents a stored “1.” Reading a device in the programmed state will cause the device to conduct heavily, while reading a device in the non-programmed state the device will not conduct. Each floating gate transistor in the array has a common source line and the common source line requires sophisticated fabrication techniques.

The present invention provides a floating gate device structure and method to fabricate a floating gate device having a floating gate electrode formed from epitaxial silicon that will provide enhanced operation of a flash memory cell device.

### SUMMARY OF THE INVENTION

Exemplary implementations of the present invention comprise a flash memory device and processes to fabricate a flash memory device.

A first exemplary implementation of the present invention includes a flash memory device comprising: an epitaxial silicon floating gate containing conductive ions and overlying a tunnel oxide material. In addition to the epitaxial silicon floating gate the following material may be added to form a floating gate device, including an inner-dielectric material overlying the epitaxial silicon floating gate; a polycide material overlying the inner-dielectric material, the tunnel oxide material, the epitaxial silicon floating gate, the inner-dielectric material and the polycide material forming a transistor gate; and source and drain electrodes on opposing sides of the transistor gate.

A second exemplary implementation of the present invention includes process steps for forming a flash memory device on a semiconductor assembly, comprising the steps of: forming a tunnel oxide with openings therein to expose underlying silicon; forming a conductively doped epitaxial silicon layer over the tunnel oxide by using the exposed underlying silicon as a silicon seeding source; and patterning the conductively doped epitaxial silicon layer into a floating gate portion of the floating gate device. The transistor may be completed by forming an inner-dielectric layer over the epitaxial silicon layer; forming a polycide layer over the inner-dielectric layer; forming transistor gates from the polycide layer, the inner-dielectric layer, the epitaxial silicon layer and the tunnel oxide; and forming source and drain electrodes on opposing sides of the transistor gates.

### BRIEF DESCRIPTION OF THE DRAWINGS

FIG. 1 is a top-down view depicting the layout of an array of flash cells, each cell utilizing a floating gate electrode using epitaxial silicon overgrowth.

FIG. 2 is a cross-sectional view taken through the drain contact region (line 1-1′) of FIG. 1 after the definition of active areas and shallow trench isolation.

FIG. 3 is a cross-sectional view following the cross-sectional view of FIG. 2 taken after etching seed windows through the tunnel oxide.

FIG. 4 is a cross-sectional view following the cross-sectional view of FIG. 3 taken after a layer of epitaxial silicon is grown.

FIG. 5 is a cross-sectional view taken through the active area (line 2-2′) of FIG. 1 after a layer of epitaxial silicon is grown.

FIG. 6 is a cross-sectional view following the cross-sectional view of FIG. 5, taken after the remaining transistor gate stack materials are formed comprising an inner-layer dielectric, a polysilicon layer and a polycide layer.

FIG. 7 is a cross-sectional view following the cross-sectional view of FIG. 6, taken after the transistor gate stack materials are patterned to form the transistor gate.

FIG. 8 is a cross-sectional view following the cross-sectional view of FIG. 7, taken after a source/drain conductive ion implant.

FIG. 9 is a cross-sectional view following the cross-sectional view of FIG. 8, showing a completed flash cell including a drain electrode contact plug and isolation material covering the flash cell.

### DETAILED DESCRIPTION OF THE INVENTION

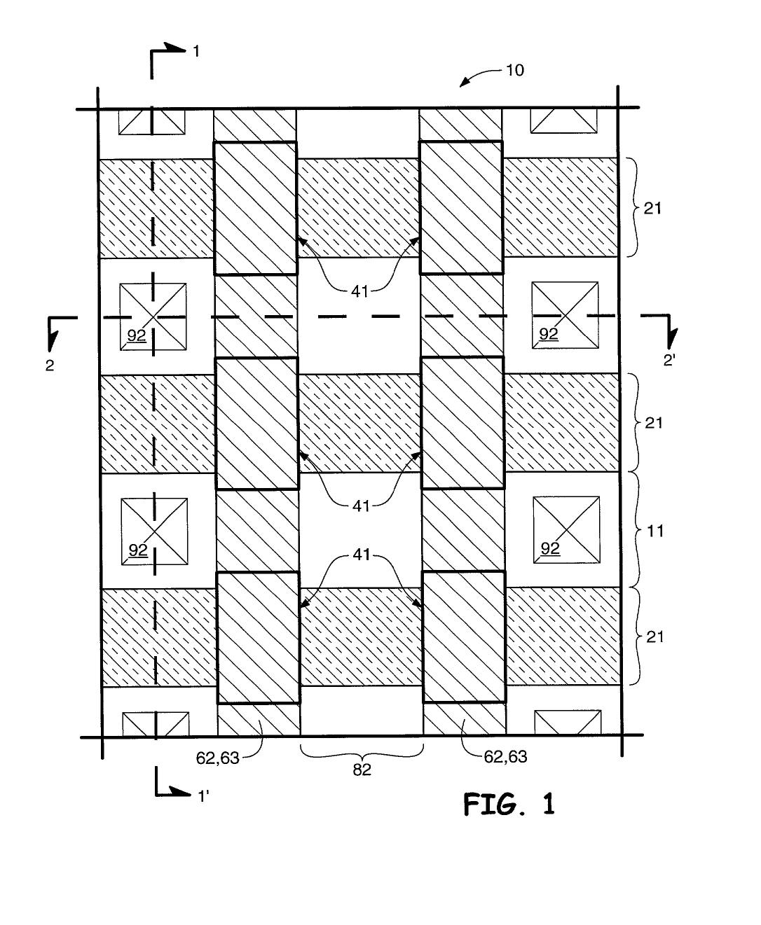

Exemplary implementations of the present invention directed to processes for fabricating a floating gate memory device are depicted in FIGS. 1-9.

Referring now to the top-down view of FIG. 1, a layout of the flash cell on wafer substrate 10 is presented. Active areas 11 define the location of a source region 82 and a drain and channel region of the floating gate devices to be formed. Shallow trench isolation 21 provides isolation between neighboring gate devices. Wordlines 62, 63 run horizontally and overlie the floating gates 41. Floating gates 41 span between the source and drains of each floating gate device that reside in the confines of active areas 11. Drain contacts 92 make contact to underlying drains.

FIG. 2 is a cross-sectional view of FIG. 1 taken through the drain contact region of the flash cell (line 1-1′). Referring now to FIG. 2, shallow trench isolation 21 have been formed into substrate 10. Tunnel oxide 22 has also been formed overlying substrate 10. The location of yet to be formed drain contacts 23 is also shown.

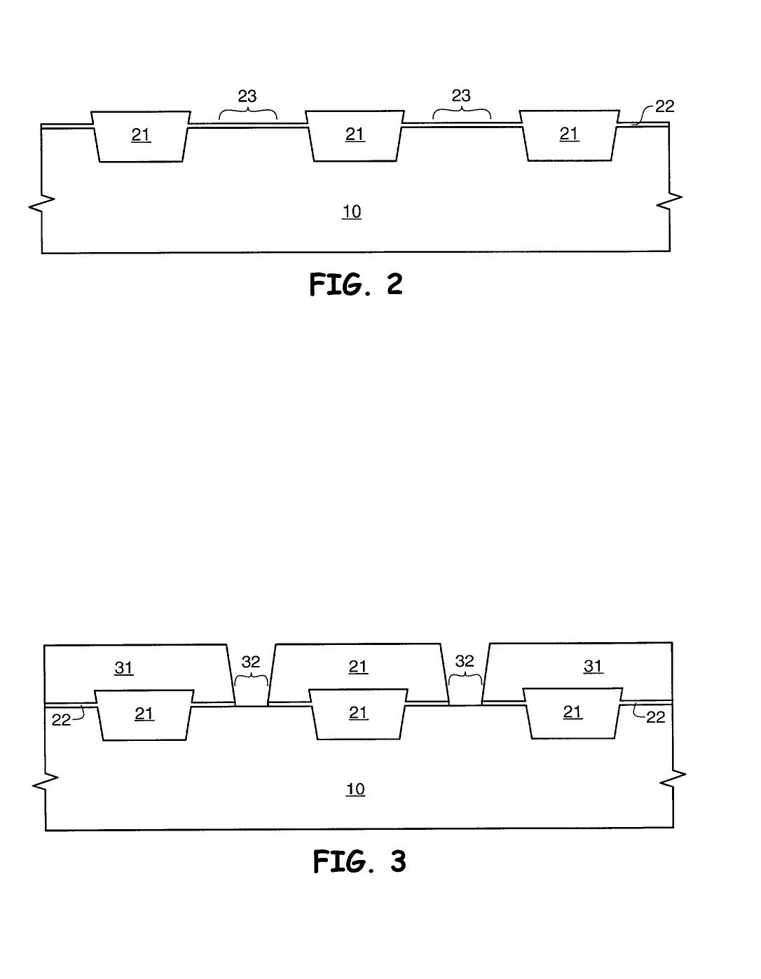

Referring now to FIG. 3, photoresist material 31 is patterned and etched to create seed window openings 32 through tunnel oxide 22. Seed window openings 32 expose underlying silicon substrate 10.

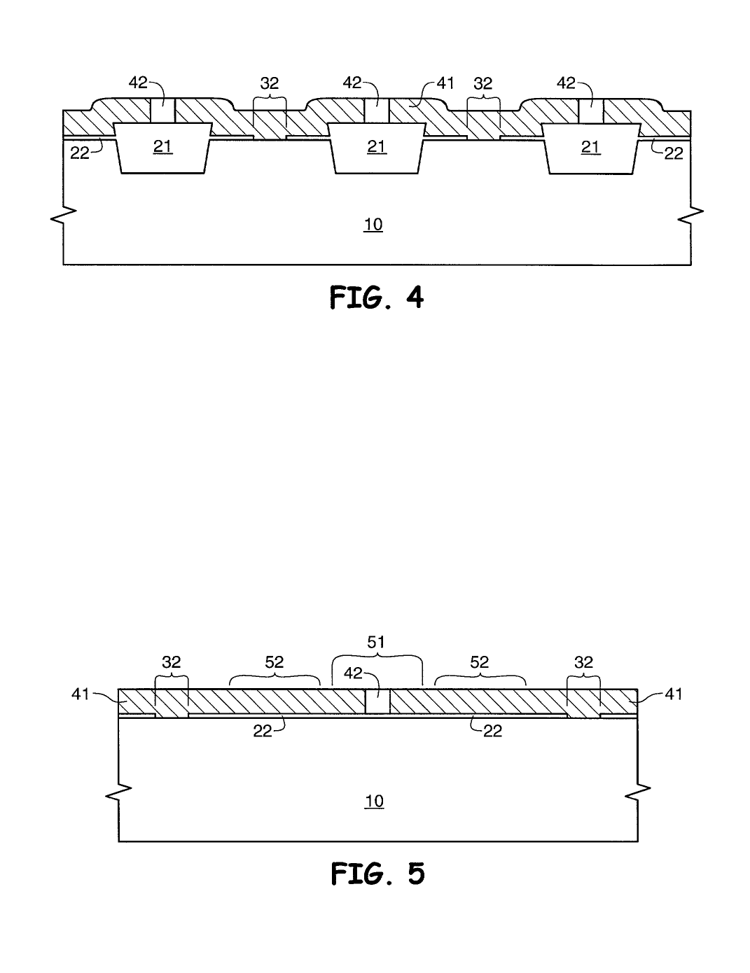

Referring now to FIG. 4, a silicon epitaxial layer 41 is grown over shallow trench isolation 21 and tunnel oxide 22. The growth of silicon epitaxial layer 41 is accomplished by several methods. One method uses the exposed underlying silicon as silicon seed to during the deposition epitaxial silicon. Another method utilizes a process known as solid phase epitaxy (SPE) of a deposited amorphous silicon layer. Both methods are well known to those skilled in the art. Other epitaxial overgrowth processes known to one skilled in the art may be used as well.

Regardless of the method used to form the epitaxial material, the silicon epitaxial layer 41 will become a key element of the flash memory device of the present invention as discussed later. Whether it be a silicon epitaxial layer, a solid phase epitaxy deposited amorphous silicon layer, or any other epitaxial silicon layer deposited by epitaxial overgrowth, layer 41 can be conductively doped by insitu doping or by ion implanting.

Also shown in FIG. 4 are the non-epitaxial regions 42 that in essence are the boundaries between the epitaxial overgrowth. Non-epitaxial regions 42 will be removed during the transistor gate pattern and etch and silicon seed openings 32 will be removed during the drain contact etch. Thus, neither non-epitaxial regions 42 or and silicon seed openings 32 will be part of the final cell structure.

FIG. 5 is a cross-sectional view taken through the active area of a flash cell and follows the view taken through line 2-2′. FIG. 5 shows tunnel oxide 22 and seed windows 32 overlaid with epitaxial overgrowth 41. Also shown are future source region 51 spanning across non-epitaxial region 42 and future location of the floating gate, which will underlie the word line.

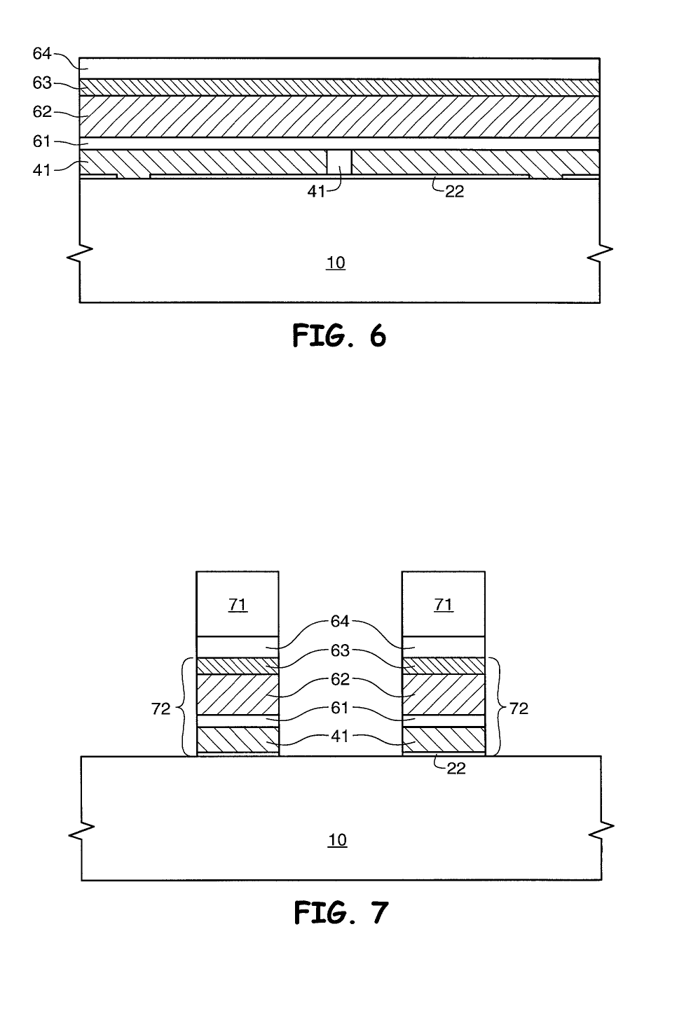

FIG. 6 depicts the results after various materials have been deposited to form the transistor gate stack for each floating gate device. The transistor gate stack comprises tunnel oxide 22, epitaxial silicon floating gate material 41, an inter-dielectric layer (such as an oxide/nitride/oxide stack) 61 and polysilicon wordline material 62, which is typically capped with tungsten silicide 63 (both layers combined are defined as polycide) and an oxide or nitride capping layer 64.

Referring now to FIG. 7, photoresist 71 is patterned and an etch is performed to create the final transistor gate stack 72 for a floating gate device.

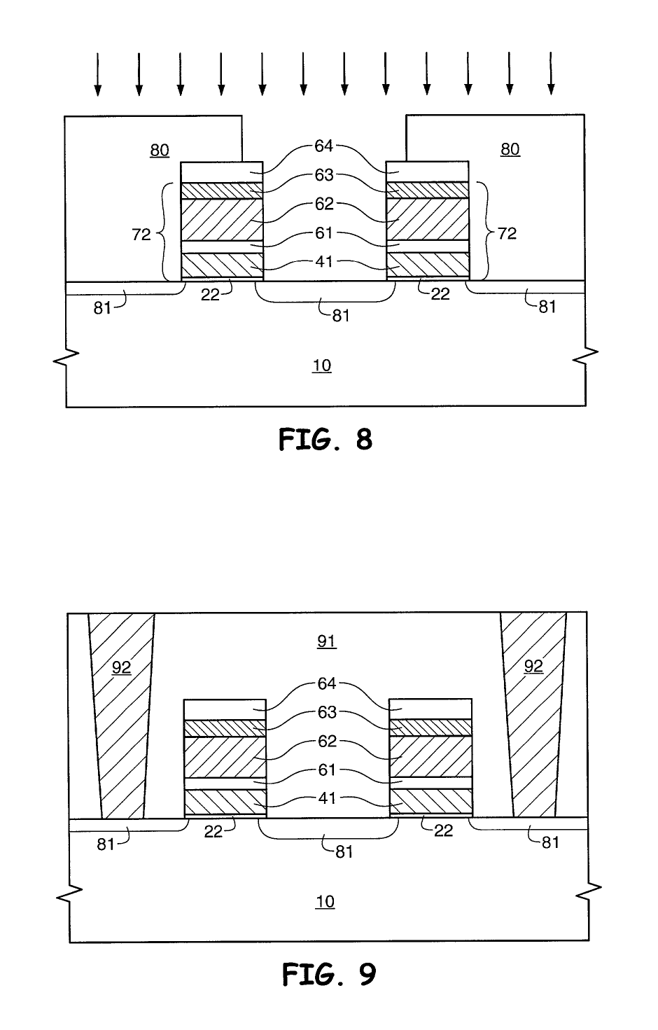

Referring now to FIG. 8, photoresist 80 is patterned and etch to allow a subsequent phosphorous and/or arsenic source implant to be performed to form self-aligned source region 82. The phosphorus and/or arsenic source implant creates a source region that directly aligns itself to the transistor gate, thus the term self-aligned source. Next, photoresist 80 is stripped and a blanket arsenic source/drain implant is performed to simultaneously form drain regions 81 and to provide a deeper self-aligned source region 82.

FIG. 9 shows a completed flash memory cell, where the transistor gate is covered with isolation material, such as borophosphosilicate glass (BPSG) 91. Drain contacts 92 have been formed into the BPSG material 64.

The presence of an epitaxial silicon floating gate provides significant advantages for the operation of the floating gate device. Due to the grain-less nature of epitaxial silicon, the transfer of charge onto and removed from the floating gate is consistent across the entire surface of the floating gate. With conventional polysilicon floating gates, charge transfer tends to be enhanced at the polysilicon grain boundaries resulting in enhanced tunneling and thus the charge transfer is not consistently distributed across the entire floating gate.

Enhanced tunneling at the polysilicon grain boundaries affect the program/erase uniformity of the device as well as the speed, cycling and data retention. With the elimination of the grain boundaries in the floating gate, the device becomes dependent on only the tunnel oxide quality and thus allows a more controlled program and erase function, as well as enhanced data retention, speed and cycling endurance.

As demonstrated by the teachings of the present invention, an epitaxial silicon floating gate can be effectively incorporated into conventional flash memory device fabrication methods and enhance operation.

It is to be understood that although the present invention has been described with reference to several preferred embodiments, various modifications, known to those skilled in the art, may be made to the process steps presented herein without departing from the invention as recited in the several claims appended hereto.

What is claimed is:

1. A method for forming a floating gate for a flash memory device in a semiconductor assembly, comprising the steps of:
forming a tunnel oxide with openings therein to expose underlying silicon;
forming an epitaxial silicon layer over said tunnel oxide by using said exposed underlying silicon as a silicon seeding source; and
patterning said epitaxial silicon layer into said floating gate.

2. The method of claim 1, wherein said step of forming an epitaxial silicon layer further comprises depositing epitaxial silicon.

3. The method of claim 1, wherein said step of forming an epitaxial silicon layer further comprises using solid phase epitaxy of a deposited amorphous silicon layer.

4. The method of claim 1, wherein said step of forming an epitaxial silicon layer further comprises conductively doping said epitaxial silicon layer.

5. The method of claim 4, wherein said step of conductively doping said epitaxial silicon layer comprises insitu doping.

6. The method of claim 4, wherein said step of conductively doping said epitaxial silicon layer comprises ion implant doping.

7. A method for forming a flash memory device in a semiconductor assembly, comprising the steps of:
forming a tunnel oxide with openings therein to expose underlying silicon;
forming an epitaxial silicon layer over said tunnel oxide by using said exposed underlying silicon as a silicon seeding source;
forming an inner-dielectric layer over said epitaxial silicon layer;
forming a polycide layer over said inner-dielectric layer;
forming transistor gates from said polycide layer, said inner-dielectric layer, said epitaxial silicon layer and said tunnel oxide; and
forming source and drain electrodes on opposing sides of said transistor gates.

8. The method of claim 7, wherein said step of forming an epitaxial silicon layer further comprises depositing epitaxial silicon.

9. The method of claim 7, wherein said step of forming an epitaxial silicon layer further comprises using solid phase epitaxy of a deposited amorphous silicon layer.

10. The method of claim 7, wherein said step of forming an epitaxial silicon layer further comprises conductively doping said epitaxial silicon layer.

11. The method of claim 10, wherein said step of conductively doping said epitaxial silicon layer comprises insitu doping.

12 The method of claim 10, wherein said step of conductively doping said epitaxial silicon layer comprises ion implant doping.

13. A floating gate for a flash memory device in a semiconductor assembly, comprising:
an epitaxial silicon floating gate overlying a tunnel oxide by using said exposed underlying silicon as a silicon seeding source.

14. The floating gate of claim 13, wherein said epitaxial silicon floating gate comprises conductive ions.

15. A flash memory device in a semiconductor assembly, comprising:
an epitaxial silicon floating gate containing conductive ions and overlying a tunnel oxide material;
an inner-dielectric material overlying said epitaxial silicon floating gate
a polycide material over said inner-dielectric material, said tunnel oxide material, said epitaxial silicon floating gate, said inner-dielectric material and said polycide material forming a transistor gate; and
source and drain electrodes on opposing sides of said transistor gate.
